(19) United States
(12) Patent Application Publication
(10) Pub. No.: US 2026/0018441 A1
(43) Pub. Date: Jan. 15, 2026

(54) SYSTEMS FOR TRANSPORTING A PLURALITY OF SEMICONDUCTOR STRUCTURES

(71) Applicant: GlobalWafers Co., Ltd., Hsinchu (TW)

(72) Inventors: Peter D. Albrecht, O'Fallon, MO (US); Brian Schulte, Wentzville, MO (US); William L. Luter, St. Charles, MO (US)

(21) Appl. No.: 19/260,988

(22) Filed: Jul. 7, 2025

Related U.S. Application Data
(60) Provisional application No. 63/669,524, filed on Jul. 10, 2024.

(51) Int. Cl. H01L 21/673

(52) U.S. Cl. CPC H01L 21/67309; H01L 21/67306

(57) ABSTRACT

Systems for transporting a plurality of semiconductor structures, wafer boats for holding the plurality of semiconductor structures and methods for heating a set of semiconductor wafers. In some embodiments, the wafer boat frame is made of a metal and the combs are made of quartz. The wafer boats may include one or more combs that are able to float within a comb holder during heating of the wafer boat.

### CROSS-REFERENCE TO RELATED APPLICATION

This application claims the benefit of U.S. Provisional Patent Application No. 63/669,524, filed Jul. 10, 2024, which is incorporated herein by reference in its entirety.

### TECHNICAL FIELD

The field of the disclosure relates to systems for transporting a plurality of semiconductor structures and to wafer boats for holding the plurality of semiconductor structures.

### BACKGROUND

“Wafer boats” or “furnace boats” hold semiconductor structures during heating. Conventional wafer boats are made entirely of quartz, silicon carbide, silicon, graphite, alumina, or some combination. Conventional wafer boats are relatively expensive and fragile. Usually, wafer boats must be repaired by outside vendors and typically have long lead times for fabrication. Wafer boats used in thermal processes (e.g., bonded wafer thermal treatments) should be strong, relatively inexpensive, functional, and acceptable for the intended wafer production process.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a wafer boat for supporting a plurality of semiconductor structures in a furnace. The wafer boat includes a comb, a lower comb holder, and an upper comb holder. The comb defines slots for receiving a semiconductor structure. The comb is attached to the lower comb holder at a first end of the comb. The comb is disposed within the upper comb holder at a second end of the comb. The comb and upper comb holder are configured to enable the comb to float within the upper comb holder.

Another aspect of the present disclosure is directed to a system for transporting a plurality of semiconductor structures. The system includes a wafer boat for supporting a plurality of semiconductor structures and a slide assembly for moving the wafer boat along a slide axis. The wafer boat includes a plurality of support surfaces for supporting a plurality of semiconductor structures, a lower end plate, an upper end plate, a back plate, and a wafer boat mount. The plurality of support surfaces are disposed between the lower end plate and the upper end plate. The lower end plate and upper end plate extend from the back plate. The wafer boat mount is connected to the lower end plate. The wafer boat mount defines a wafer boat mount recess. The slide assembly includes a mounting ball and a support frame. The mounting ball is partially received in the wafer boat mount recess when the slide assembly is connected to the wafer boat. The support frame is disposed below the wafer boat when the slide assembly is connected to the wafer boat in a vertical orientation. The support frame supports the mounting ball.

Yet another aspect of the present disclosure is directed to a system for transporting a plurality of semiconductor structures. The system includes a wafer boat for supporting a plurality of semiconductor structures and a slide assembly for moving the wafer boat along a slide axis. The wafer boat includes a plurality of support surfaces for supporting a plurality of semiconductor structures, a lower end plate, an upper end plate, a back plate, and a hook. The plurality of support surfaces are disposed between the lower end plate and the upper end plate. The lower end plate and upper end plate extend from the back plate. The hook extends from the back plate. The slide assembly includes a support frame and a catch. The slide assembly is disposed below the wafer boat when the slide assembly is connected to the wafer boat. The catch is attached to the support frame. The catch is disposed within the hook when the wafer boat is connected to the slide assembly. The catch and hook are sized to allow the catch to slide laterally within the hook.

Yet a further aspect of the present disclosure is directed to a method for heating a set of semiconductor structures. The set of semiconductor structures is loaded onto a wafer boat. The wafer boat includes a plurality of combs, a plurality of lower comb holders, and a plurality of upper comb holders. The plurality of combs define slots for receiving a semiconductor structure of the set of semiconductor structures. Each comb is attached to a lower comb holder at a first end of the comb. Each comb is disposed within an upper comb holder at a second end of the comb. The comb and upper comb holder are configured to enable the comb to float within the upper comb holder. The set of semiconductor structures and wafer boat are positioned in a furnace. The set of semiconductor structures and wafer boat disposed in the furnace are heated. Each comb slides within the upper comb holder as the wafer boat heats.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a perspective view of a wafer boat holding a set of semiconductor structures;

FIG. 2 is a front view of the wafer boat;

FIG. 3 is an exploded view of a comb and a lower comb holder of the wafer boat;

FIG. 4 is an exploded view of a comb and an upper comb holder of the wafer boat;

FIG. 5 is another perspective view of the wafer boat;

FIG. 6 is a side view of a slide assembly which supports the wafer boat;

FIG. 7 is a detailed cross-section view of the slide assembly and wafer boat showing a ball and socket joint and a leveling system of the slide assembly; and

FIG. 8 is a detailed side view of a hook of the wafer boat disposed on a catch of the slide assembly.

Corresponding reference characters indicate corresponding parts throughout the drawings.

### DETAILED DESCRIPTION

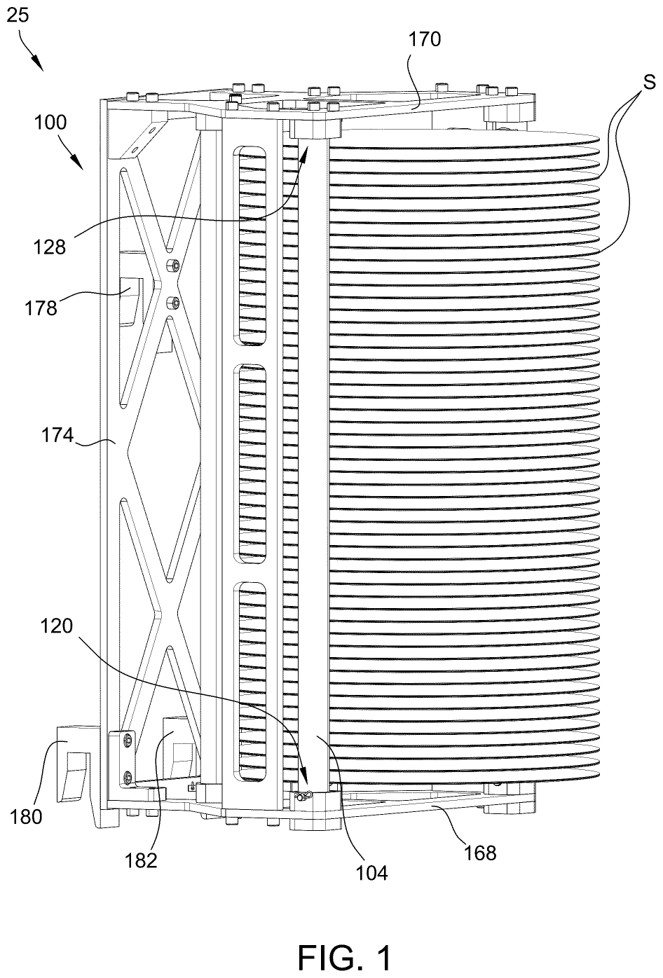

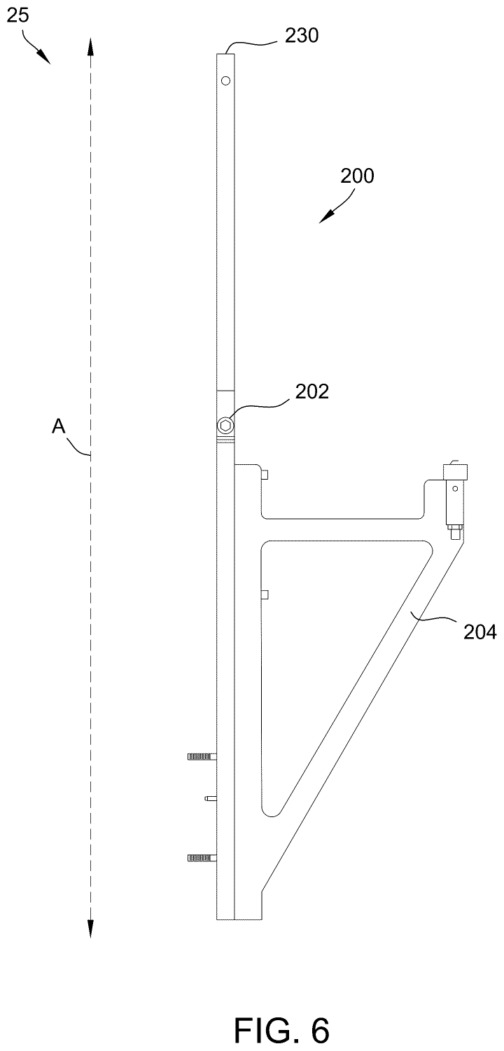

Provisions of the present disclosure relate to a system 25 (FIGS. 1 and 6) for transporting a plurality of semiconductor structures. The system 25 includes a wafer boat 100 (FIG. 1) and a slide assembly 200 (FIG. 6) to which the wafer boat 100 is connected to move the wafer boat 100 into and out of a furnace. In this regard, the semiconductor structures supported by the wafer boat 100 may generally be any semiconductor structure such as a single crystal silicon wafer, an epitaxial wafer or a bonded wafer structure. Generally, the wafer boat may be adapted to accommodate any diameter of semiconductor structures (e.g., 200 mm or 300 mm diameter structures).

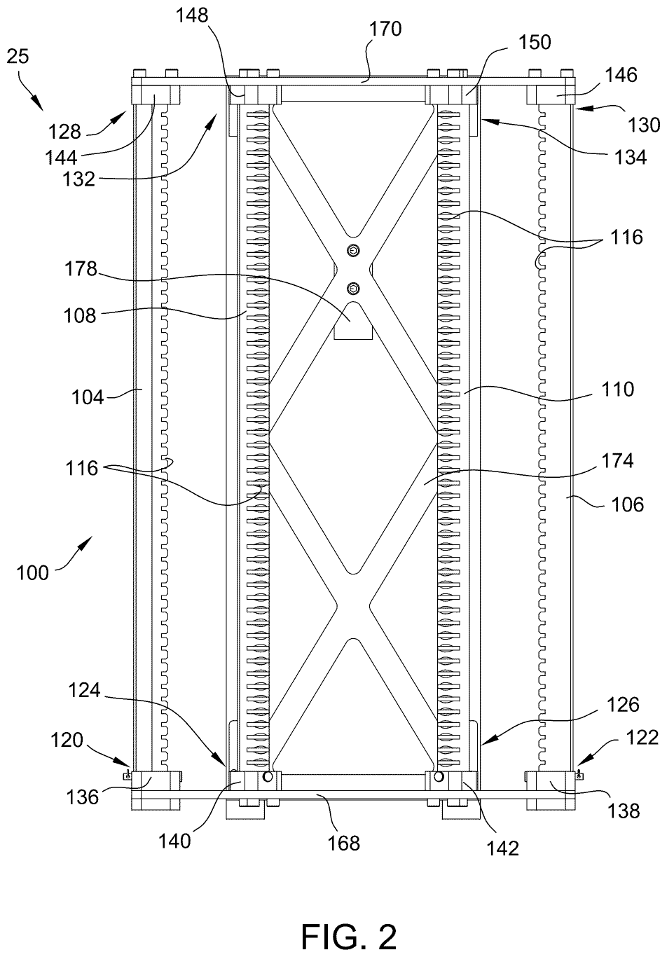

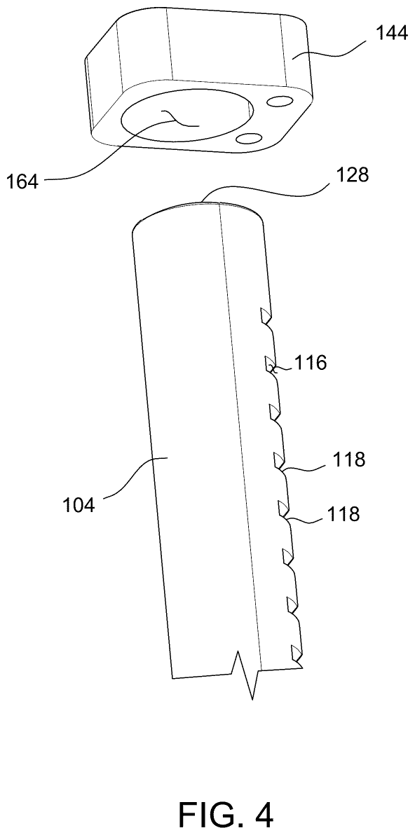

The wafer boat 100 that supports the plurality of semiconductor structures S during heating of the semiconductor structures is shown in FIGS. 1-2. The wafer boat 100 includes four combs-a first comb 104, a second comb 106, a third comb 108 and a fourth comb 110. Each comb 104, 106, 108, 110 defines slots 116 for receiving a semiconductor structure S. In this regard, the combs 104, 106, 108, 110 have parallel slots to enable a semiconductor structure S to be held in generally parallel alignment. Each slot 116 has a support surface 118 (FIG. 4) capable of supporting the semiconductor structure S. In this regard, in the vertical position, the semiconductor may rest on less than all support surfaces of the combs (e.g., only upon the support surfaces of the first and second combs 104, 106).

Each comb 104, 106, 108, 110 extends between a lower end plate 168 and an upper end plate 170 of the wafer boat 100. The lower end plate 168 and upper end plate 170 extend from a back plate 174. One or more hooks 178, 180, 182 (FIG. 1) extend from the back plate 172 for connecting the wafer boat 100 to a slide assembly 200 (FIG. 6). For example, the wafer boat 100 may include an upper hook 178 and first and second lower hooks 180, 182 that extend from the back plate 174. The slide assembly 200 moves the wafer boat 100 into and out of a furnace in which the structures S are annealed.

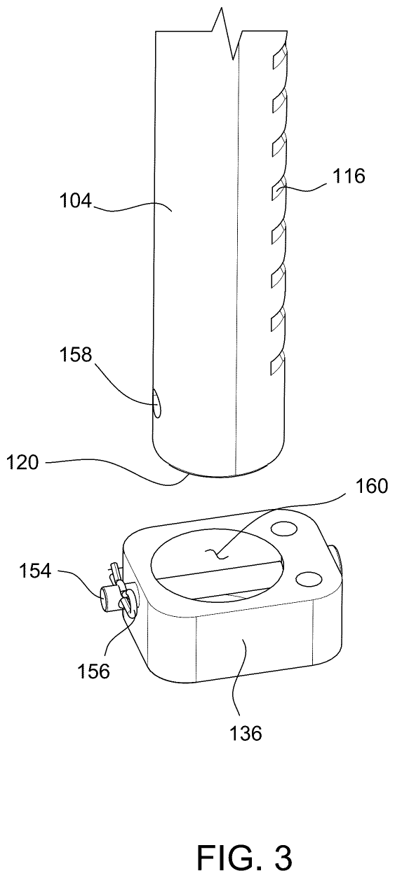

Each comb 104, 106, 108, 110 has a first (or “lower”) end 120, 122, 124, 126 and a second (or “upper”) end 128, 130, 132, 134. Each comb 104, 106, 108, 110 is attached to a lower comb holder 136, 138, 140, 142 at the first end 120, 122, 124, 126 of the comb. For example and with reference to the first lower comb holder 136 (FIG. 3), each comb holder 136 includes a clevis pin 154 and clip 156. The clevis pin 154 extends through a through-hole 158 in the comb 104. The lower end 120 of the comb 104 is disposed within an inner chamber 160 of the comb holder. Each lower comb holder 136, 138, 140, 142 is attached do the lower end plate 168.

The wafer boat 100 includes upper comb holders 144, 146, 148, 150 (FIG. 2) that are attached to the upper end plate 170. Each comb 104, 106, 108, 110 is disposed within a corresponding upper comb holder 144, 146, 148, 150 at the second end 128, 130, 132, 134 of the comb. With reference to the first upper comb holder 144 (FIG. 4), each upper comb holder 144 includes an inner chamber 164 in which the second end 128 is disposed. The comb 104 and upper comb holder 144 are configured such that the comb 104 can float within the upper comb holder 144. For example, the comb 104 is slidingly disposed within the upper comb holder 144 to allow the comb to slide within the holder 144 such as during thermal expansion of the back plate 174. The inner chamber 164 has a largest width and the comb 104 has a largest width at its second end 128. The largest width of the inner chamber 164 is larger than the largest width of the comb 104 to enable the comb 104 to slide within the inner chamber 164. In the illustrated embodiment, both the comb 104 and inner chamber 164 are circular. Other embodiments may include other shapes.

While the upper end of each comb is able to float in the upper comb holder in the illustrated embodiment, in other embodiments, the upper end is attached to the comb and the lower end of each comb is able to float in the lower comb holder.

Referring now to FIG. 3, in some embodiments, the plurality of combs 104, 106, 108, 110 and the back plate 174 are made of different materials. For example, the combs 104, 106, 108, 110 may be made of quartz and the lower end plate 168, upper end plate, 170 and back plate 174 (i.e., the frame that supports the quartz combs) may be made of a metal (e.g., stainless steel). In some embodiments, the wafer boat fasteners (e.g., screws) are made of titanium.

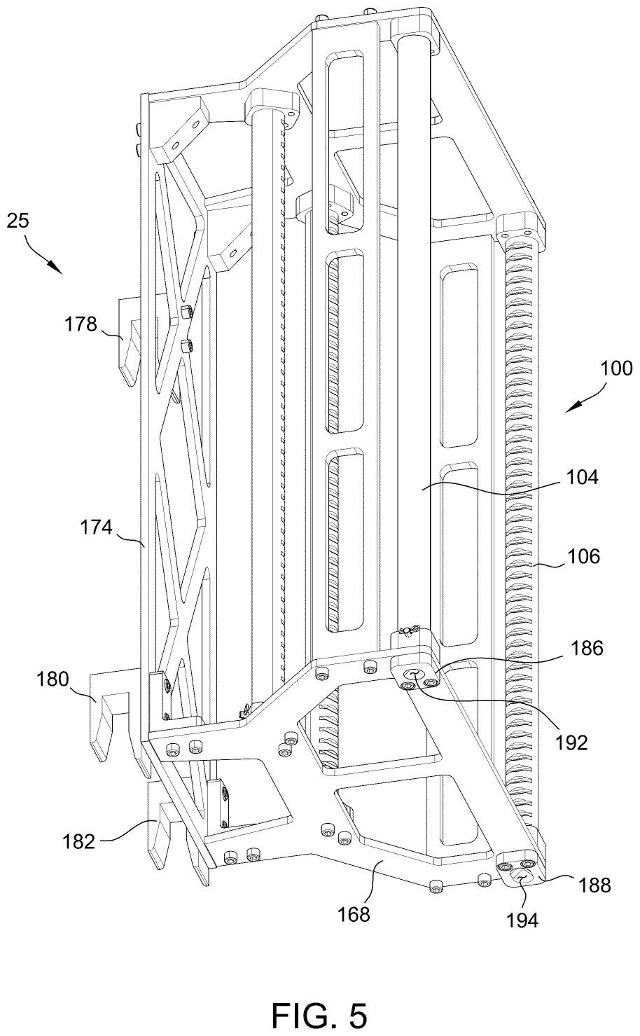

Referring now to FIG. 5, the wafer boat 100 includes first and second wafer boat mounts 186, 188 that are connected to the lower end plate 168 for connecting the wafer boat 100 to a slide assembly 200 (FIG. 6) as discussed further below. Each wafer boat mount 186, 188 includes a wafer boat mount recess 192, 194.

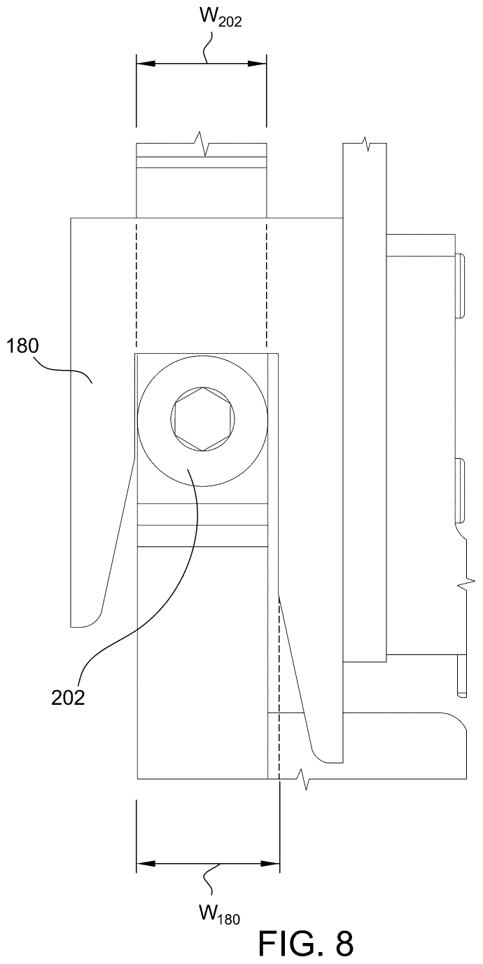

The slide assembly 200 (FIG. 6) moves the wafer boat 100 about a slide axis A. The slide assembly 200 includes a support frame 204 that is disposed below the wafer boat when the slide assembly 200 is connected to the wafer boat 100. The slide assembly 200 includes first and second catches (first catch 202 shown in FIG. 8) attached to the support frame 204. The first catch 202 is disposed within the first lower hook 180 when the wafer boat 100 is connected to the slide assembly 200. The catch 202 and hook 180 are sized to allow the catch 202 to slide laterally within the hook 180. Similarly, the second catch (not shown) is disposed within the second lower hook 182 (FIG. 5). The first and second catches may be bearings or bushings. The upper hook 178 (FIG. 5) may connect to an upper surface 230 (FIG. 6) of the support frame 204.

With reference to FIG. 8, each lower hook 180, 182 may have a hook width W₁₈₀ (i.e., the width at a vertical position of the hook at which the catch is disposed within hook). Each catch (first catch 202 shown in FIG. 8) has a catch width W₂₀₂. The catch width W₂₀₂ is less than the hook width W₁₈₀ to allow the catch 202 to move within the hook 180.

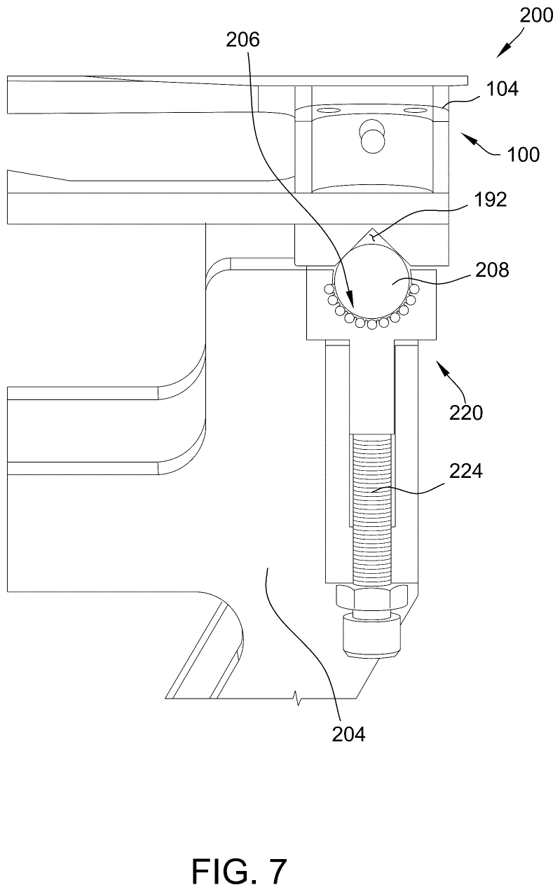

As shown in FIG. 7, the slide assembly 200 includes a first and second mounting balls (first mounting ball 208 shown in FIG. 7). The support frame 204 defines a socket 206 in which the mounting ball 208 is at least partially disposed. Each mounting ball 208 is partially received in the wafer boat mount recess 192 (as in a ball and socket joint) when the slide assembly 200 is connected to the wafer boat 100.

As shown in FIGS. 1-2, the first and second combs 104, 106 are “forward combs” (i.e., furthest from the back plate 174) and the third and fourth combs 108, 110 are “rear combs” (i.e., nearer the back plate 174). The first wafer boat mount 186 and first mounting ball 208 (FIG. 7) are disposed below the first forward comb 104 and the second wafer boat mount 188 and second mount ball (not shown) are disposed below the second forward comb 106. In the illustrated embodiment, the system 25 does not include a ball and socket joint disposed below the first rear comb 108 or the second rear comb 110.

In the illustrated embodiment, the wafer boat 100 includes two rear combs 108 110. In other embodiments, the wafer boat may include a single rear comb (or more than two rear combs).

The system 25 may include a leveling system 220 (FIG. 7) for leveling the wafer boat 100. For example, the leveling system 220 may include a first jack screw 224 for adjusting the height of the first mounting ball and a second jack screw (not shown) for adjusting the height of the second mounting ball.

In some embodiments, the mounting balls, first and second lower hooks and lower ends of the combs are about at the same vertical position relative to the vertical axis of the wafer boat.

The set of semiconductor structures S may be heated by loading the set of semiconductor structures S onto the wafer boat 100 as shown in FIG. 1. The wafer boat 100 is connected to the slide assembly 200 (e.g., before or after loading the structures) by positioning the first and second catches in the first and second lower hooks 180, 182. In the vertical orientation of the wafer boat 100, the wafer boat 100 is supported by the slide assembly 200 by the mounting balls 208 and lower hooks 180, 182 (e.g., only by the mounting balls and lower hooks). In this regard, in some embodiments, the upper hook 178 does not support the wafer boat 100 when the wafer boat 100 is in its vertical orientation. The wafer boat 100 and set of semiconductor structures are positioned in a furnace by the sliding assembly 200. The set of semiconductor structures S and wafer boat 100 are heated while disposed in the furnace. As the back plate 174 extends due to thermal expansion, each comb slides within the upper comb holder 144, 146, 148, 150 as the wafer boat heats.

In some embodiments, the wafer boat 100 is a horizontal orientation when in the furnace (lying on the back side of hooks 178, 180, 182 with the semiconductor structures lying on the rear combs 108, 110). The wafer boat 100 goes from vertical when loading to horizontal by a tilt-slide which extends to place the wafer boat in the furnace).

In some embodiments, the upper hook 178 does not support the wafer boat 100 in its vertical orientation. The upper hook 178 may support the wafer boat 100 when the wafer boat is in a horizontal orientation. The upper hook 178 supports the boat when tilting the boat into the furnace and when the boat is horizontally at rest in the furnace.

Compared to conventional wafer boats, the wafer boats of the present disclosure have several advantages. The combs (e.g., quartz combs) are supported by their lower ends only and the upper ends are allowed to float. As the back plate (e.g., made of stainless steel) of the wafer boat expands and contacts relative to the combs (e.g., made of quartz), the combs may slide in the upper comb holders.

The lower hooks and ball and socket joints below the forward combs support the wafer boat. The ball and socket joints and first and second lower hooks may be about at the same vertical position as the lower end of the combs which reduces vertical error due to thermal expansion of the boat frame. The ball and socket joints locate the wafer boat horizontally. The hooks allow for thermal expansion.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A system for transporting a plurality of semiconductor structures comprising:
a wafer boat for supporting a plurality of semiconductor structures, the wafer boat comprising:
a plurality of support surfaces for supporting a plurality of semiconductor structures;
a lower end plate;
an upper end plate, the plurality of support surfaces being disposed between the lower end plate and the upper end plate;
a back plate, the lower end plate and upper end plate extending from the back plate; and
a wafer boat mount connected to the lower end plate, the wafer boat mount defining a wafer boat mount recess;
a slide assembly for moving the wafer boat along a slide axis, the slide assembly comprising:
a mounting ball, the mounting ball being partially received in the wafer boat mount recess when the slide assembly is connected to the wafer boat; and
a support frame disposed below the wafer boat when the slide assembly is connected to the wafer boat an in a vertical orientation, wherein the support frame supports the mounting ball.

2. The system as set forth in claim 1 comprising a plurality of combs on which the plurality of support surfaces are disposed, the plurality of support surfaces comprising a forward comb, the wafer boat mount and mounting ball being disposed below the forward comb.

3. The system as set forth in claim 1 wherein the support frame defines a socket in which the mounting ball is at least partially disposed.

4. The system as set forth in claim 1 wherein the wafer boat mount is a first wafer boat mount, the wafer boat mount recess is a first wafer boat mount recess, the mounting ball is a first mounting ball, the forward comb being a first forward comb, the plurality of combs comprising a second forward comb, the slide assembly further comprising:
a second mounting ball, the second mounting ball being partially received in the second wafer boat mount recess when the slide assembly is connected to the wafer boat, the support frame supporting the second mounting ball, the second wafer boat mount and the second mounting ball being disposed below the second forward comb.

5. The system as set forth in claim 4 wherein the plurality of combs comprises:
a first rear comb; and
a second rear comb, wherein the system does not include a ball and socket joint disposed below the first rear comb or second rear comb.

6. The system as set forth in claim 4 comprising a leveling system for leveling the wafer boat.

7. The system as set forth in claim 6 wherein the leveling system comprises a jack screw for adjusting the height of the first mounting ball.

8. The system as set forth in claim 7 wherein the jack screw is a first jack screw, the leveling system comprising a second jack screw for adjusting the height of the second mounting ball.

9. The system as set forth in claim 1 wherein the wafer boat comprises:
an upper hook that extends from the back plate for connecting the wafer boat to the slide assembly; and
first and second lower hooks that extend from the back plate for connecting the wafer boat to the slide assembly.

10. A system for transporting a plurality of semiconductor structures comprising:
a wafer boat for supporting a plurality of semiconductor structures, the wafer boat comprising:
a plurality of support surfaces for supporting a plurality of semiconductor structures;
a lower end plate;
an upper end plate, the plurality of support surfaces being disposed between the lower end plate and the upper end plate;
a back plate, the lower end plate and upper end plate extending from the back plate; and
a hook that extends from the back plate;
a slide assembly for moving the wafer boat along a slide axis, the slide assembly comprising:
a support frame disposed below the wafer boat when the slide assembly is connected to the wafer boat; and
a catch attached to the support frame, the catch being disposed within the hook when the wafer boat is connected to the slide assembly, wherein the catch and hook are sized to allow the catch to slide laterally within the hook.

11. The system as set forth in claim 10 wherein the catch has a catch width and the hook defines a hook width at a vertical position of the hook at which the catch is disposed within hook, the catch width being less than the hook width.

12. The system as set forth in claim 11 wherein the catch is a bushing.

13. The system as set forth in claim 10 wherein the hook is a first hook and the catch is a first catch, the wafer boat comprising a second hook, the slide assembly comprising a second catch attached to the support frame, the second catch being disposed within the second hook when the wafer boat is connected to the slide assembly, wherein the second catch and second hook are sized to allow the second catch to slide laterally within the second hook.

14. The system as set forth in claim 13 wherein the first hook is a first lower hook and the second hook is a second lower hook, the wafer boat comprising an upper hook that extends from the back plate.
